(19) United States
(12) Patent Application Publication
(10) Pub. No.: US 2025/0372382 A1
(43) Pub. Date: Dec. 4, 2025

(54) Treatments for Improving Fracture Strength for Semiconductor Workpiece

(71) Applicant: Wolfspeed, Inc., Durham, NC (US)

(72) Inventors: Joseph Taylor Budd, Pittsboro, NC (US); Davis Andrew McClure, Raleigh, NC (US); Victor V. Aristov, Holly Springs, NC (US)

(21) Appl. No.: 18/680,764

(22) Filed: May 31, 2024

(51) Int. Cl. H01L 21/04

(52) U.S. Cl. CPC H01L 21/0445

(57) ABSTRACT

Systems and methods for increasing fracture strength of a semiconductor workpiece (e.g., silicon carbide) are provided. In some examples, a method includes removing a semiconductor wafer from a boule. The method includes implementing a treatment process on the semiconductor wafer removed from the boule. The treatment process includes a thermal treatment process or a chemical etching process. The treatment process provides a fracture strength of the semiconductor wafer in a range of about 17.5 Newtons or greater, such as in a range of about 17.5 Newtons to about 75 Newtons.

### FIELD

The present disclosure relates to semiconductor fabrication, and more particularly to treatments for improving fracture strength of semiconductor workpieces, such as wide bandgap semiconductor workpieces, such as silicon carbide semiconductor workpieces.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or may be learned from the description, or may be learned through practice of the embodiments.

In an aspect, an example method of processing a crystalline semiconductor workpiece includes removing a semiconductor wafer from a boule. The method includes implementing a treatment process on the semiconductor wafer removed from the boule. The treatment process includes a thermal treatment process or a chemical etching process. The treatment process provides a fracture strength of the semiconductor wafer in a range of about 17.5 Newtons or greater.

In an aspect, the present disclosure provides an example system. In some implementations, the example system includes a treatment chamber. In some implementations, the example system includes a workpiece holder operable to hold a silicon carbide semiconductor wafer removed on from a boule. In some implementations, the example system includes control circuitry configured to implement a non-mechanical treatment process on the semiconductor wafer to increase a fracture strength of the semiconductor wafer.

In an aspect, the present disclosure provides an example method for treating a silicon carbide semiconductor workpiece to increase a fracture strength of the semiconductor workpiece. In some implementations, the example method includes heating the silicon carbide semiconductor workpiece at a temperature in a range of about 1000° C. to about 2000° C.

In an aspect, the present disclosure provides an example method for treating a silicon carbide semiconductor workpiece to increase a fracture strength of the semiconductor workpiece. In some implementations, the example method includes exposing the silicon carbide semiconductor workpiece to a wet chemical etchant at a temperature in range of about at a temperature in a range of about 15° C. to about 100° C.

In an aspect, the present disclosure provides an example method. The method includes removing a semiconductor wafer from a boule. The method includes implementing a treatment process on the semiconductor wafer removed from the boule, the treatment process comprising a thermal treatment process or a chemical etching process; and wherein the treatment process increases a fracture strength of the semiconductor workpiece by about 15% or greater.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 is a first perspective view crystal plane diagram showing the coordinate system for a hexagonal crystal such as 4H-SiC.

FIG. 2 is a second perspective view crystal plane diagram for a hexagonal crystal, illustrating a vicinal plane that is non-parallel to the c-plane.

FIG. 3A is a perspective view wafer orientation diagram showing orientation of a vicinal wafer relative to the c-plane.

FIG. 3B is a simplified cross-sectional view of the vicinal wafer of FIG. 3A superimposed over a portion of a boule.

FIG. 3C is a perspective view of a wafer orientation diagram showing orientation of an on-axis wafer relative to the c-plane.

FIG. 3D is a simplified cross-sectional view of the wafer of FIG. 3C superimposed over a portion of a boule.

FIG. 4 is a top plan view of an exemplary silicon carbide semiconductor wafer, with superimposed arrows showing crystallographic orientation directions.

FIG. 5A is a side elevation schematic view of an on-axis boule of crystalline material.

FIG. 5B is a side elevation schematic view of the boule of FIG. 5A being rotated by 4 degrees, with a superimposed pattern for cutting end portions of the boule.

FIG. 5C is a side elevation schematic view of a boule following removal of end portions to provide end faces that are non-perpendicular to the c-direction.

FIG. 5D is a side elevation schematic view of an off axis grown boule of crystalline material.

FIG. 5E is a side elevation schematic view of an off-axis grown boule having end faces that are non-perpendicular to the c-direction.

FIG. 6 depicts an overview of an example method according to examples of the present disclosure.

FIGS. 7-8 depict an example testing apparatus and method for determining fracture strength of a semiconductor workpiece according to examples of the present disclosure.

FIG. 9 depicts an example treatment chamber according to examples of the present disclosure.

FIG. 10 depicts example results of a treatment process on fracture strength of a silicon carbide semiconductor wafer according to examples of the present disclosure.

FIG. 11 depicts an example treatment chamber according to examples of the present disclosure.

FIG. 12 depicts example results of a treatment process on fracture strength of a silicon carbide semiconductor wafer according to examples of the present disclosure.

FIG. 13 depicts an example treatment chamber according to examples of the present disclosure.

FIG. 14 depicts example results of a treatment process on fracture strength of a silicon carbide semiconductor wafer according to examples of the present disclosure.

FIG. 15 depicts an example treatment chamber according to examples of the present disclosure.

FIG. 16 depicts a flow chart diagram of an example method according to examples of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that the power semiconductor devices according to example embodiments of the present disclosure may be used with any semiconductor material, such as other wide bandgap semiconductor materials and other semiconductor materials (e.g., silicon), without deviating from the scope of the present disclosure. Example wide bandgap semiconductor materials include silicon carbide and the Group III-nitrides.

Power semiconductor devices may be fabricated using epitaxial layers formed on a semiconductor workpiece, such as a silicon carbide semiconductor wafer. Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces, such as other wide bandgap semiconductor workpieces. Other semiconductor workpieces may include carrier substrates, ingots, boules, polycrystalline substrates, monocrystalline substrates, bulk materials having a thickness of greater than 1 mm, such as greater than about 5 mm, such as greater than about 10 millimeters, such as greater than about 20 millimeters, such as greater than about 50 millimeters, such as greater than about 100 millimeters, such as greater than about 200 millimeters, etc.

In some examples, the semiconductor workpiece includes silicon carbide crystalline material. The silicon carbide crystalline material may have a 4H crystal structure, 6H crystal structure, or other crystal structure. The semiconductor workpiece can be an on-axis workpiece (e.g., end face parallel to the (0001) plane) or an off-axis workpiece (e.g., end face non-parallel to the (0001) plane).

Aspects of the present disclosure may make reference to a surface of the semiconductor workpiece. In some examples, the surface of the workpiece may be, for instance, a silicon face of the workpiece. In some examples, the surface of the workpiece may be, for instance, a carbon face of the workpiece.

An ingot or boule refers to a large portion of semiconductor material used in forming semiconductor substrates, commonly semiconductor wafers. A boule may be part of an epitaxially grown crystalline semiconductor material, for example, a wide bandgap semiconductor material. Specifically, in some examples, a boule may include a large portion of epitaxially grown silicon carbide (e.g., 4H silicon carbide) or Group III-nitride. A substrate or semiconductor wafer may be formed from a portion of semiconductor material removed from a boule. The terms “ingot” and “boule” may be used interchangeably in the present disclosure.

In some examples, a semiconductor wafer may be a solid semiconductor workpiece upon which semiconductor device fabrication (e.g., fabrication of MOSFETs, Schottky diodes, HEMTs, FETs) may be implemented. A semiconductor wafer may be a homogenous material, such as silicon carbide, and may provide mechanical support for the formation and/or carrying of additional semiconductor layers (e.g., epitaxial layers), metallization layers, and other layers to form one or more semiconductor devices. In some examples, a semiconductor wafer may have a thickness in a range of about 0.5 micron to about 1000 microns, such as about 100 microns to about 800 microns, such as about 150 microns to about 500 microns.

A semiconductor wafer may be characterized by a plurality of surfaces. For example, a semiconductor wafer may have a “first major surface” and a “second major surface.” The first major surface may be generally opposite the second major surface. The first and second major surfaces may be generally parallel to one another. A semiconductor wafer may also have a “side surface” corresponding to a surface extending between the two major surfaces. For example, the side surface may extend between the first major surface and the second major surface.

Power semiconductor device fabrication processes may include surface processing operations that are performed on the silicon carbide semiconductor wafer to prepare one or more surfaces of the silicon carbide semiconductor wafer for later processing steps, such as surface implantation, formation of epitaxial layers, metallization, etc. Example surface processing operations may include grinding operations, lapping operations, and polishing operations. Methods for surface processing of semiconductor wafers in semiconductor manufacturing may include grinding, lapping, and/or polishing the rough surfaces until a sufficient smoothness and/or thickness is achieved.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grinding teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disc having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

Electrochemical Mechanical Polishing (ECMP) is a specialized process used in semiconductor manufacturing for polishing and planarizing surfaces with high precision. ECMP combines the principles of electrochemical and mechanical actions to achieve highly uniform material removal rates across the surface of a semiconductor wafer. For example, a silicon carbide semiconductor wafer may be mounted or provided on a workpiece carrier, which brings the wafer into contact with a polishing pad. A slurry (including an electrolyte solution) may be applied between the semiconductor wafer and the polishing pad to facilitate the electrochemical reactions, carry away removed material, and provide lubrication for the mechanical polishing action. A bias (e.g., bias voltage and/or bias current) may be applied between the semiconductor wafer and the electrolyte solution of the slurry to drive electrochemical reactions to occur at the surface of the semiconductor wafer, leading to material dissolution. The electrochemical reactions may vary depending on the specific materials involved, but they often involve oxidation or reduction processes.

Methods for forming semiconductor wafers from boules may include, for instance, cutting thin layers (e.g., wafers) from the boule using wire saws. Another example removal process for forming semiconductor wafers from boules may include a laser-based removal process. Laser-based removal processes may include providing subsurface laser damage patterns to a boule to form weakened areas in the boule. Portions may then be separated from the boule along the weakened areas to produce semiconductor wafers. Separation processes may include, for example, ultrasonic fracturing, mechanical force fracturing, or other fracturing methods. Another example removal process for forming semiconductor wafers from boules may include an implant-based (e.g., hydrogen species implant based) removal processes. Implant-based removal processes may include providing subsurface damage patterns to a boule with implanted species (e.g., hydrogen) to form weakened areas in the boule. Portions may then be separated from the boule along the weakened areas to produce semiconductor wafers. Separation processes may include, for example, ultrasonic fracturing, mechanical force fracturing, or other fracturing methods.

Aspects of the present disclosure are discussed with reference to laser-based, saw-based, and implant-based removal and/or separation for purposes of illustration and discussion. Those of ordinary skill in the art, using the disclosures provided herein, will understand that any separation and/or removal process may be used without deviating from the scope of the present disclosure. For instance, separation of a wafer from a boule can be performed using laser-based removal, sawing and/or other separation layer inducing separation techniques, such as ion implantation, to create separation layer. This may be followed by chemical/mechanical/supplemental lasering, processing, and/or ultrasonic separation to produce a wafer.

The separation (e.g., fracturing) process may produce a rough and uneven surface on both the boule and the semiconductor wafers separated from the boule that may include a high concentration of cracks and/or voids with sharp tips. These features may act as stress concentrators that reduce a fracture strength of the semiconductor wafer. Because of this reduced fracture strength, semiconductor wafers may have an elevated breakage rate during subsequent processing operations (e.g., surface processing operations such as grinding, lapping, polishing, CMP, ECMP, etc.), which increases cost and reduces yield and capacity.

Aspects of the present disclosure are directed to implementing a treatment process to increase fracture strength, for instance, on semiconductor wafers removed from a boule or other semiconductor workpiece. The treatment process may, in some implementations, increase fracture strength by rounding sharp tips on features (e.g., cracks, voids, etc.) on the surface of the semiconductor wafer resulting from the removal process. In some examples, the treatment process may reduce a height of one or more peak topographical area on a surface of the semiconductor wafer. In some examples, the treatment process may reduce a surface roughness (e.g., Sz (maximum height) surface roughness) on a surface of the semiconductor wafer.

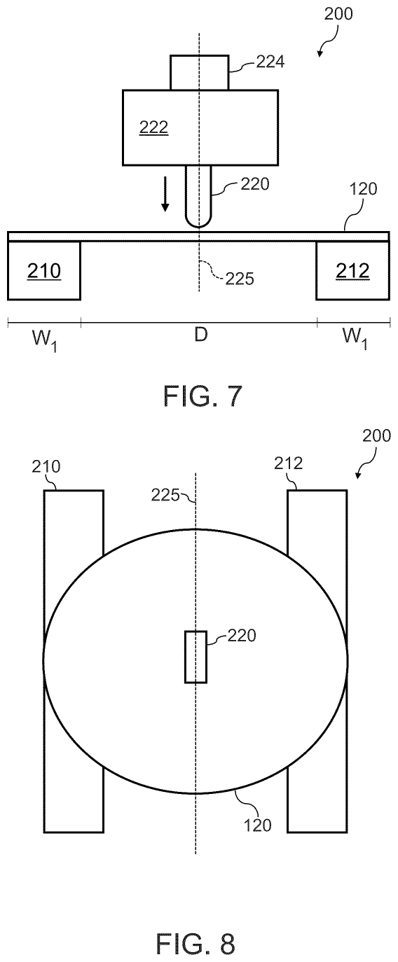

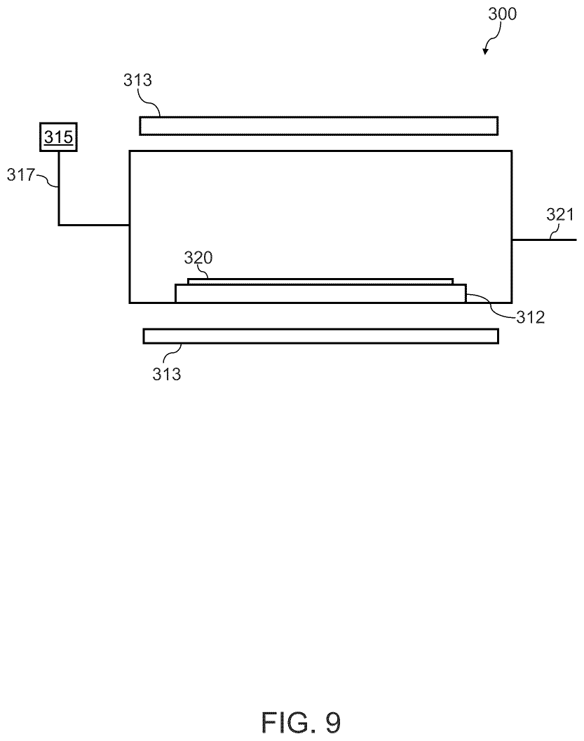

The fracture strength is the magnitude of the force needed to fracture a semiconductor workpiece when the force is applied to a first major surface of the semiconductor workpiece along a middle axis located centrally between two support structures supporting the semiconductor workpiece from a second major surface of the semiconductor workpiece, where the support structures are spaced apart by a gap of 4 inches for an approximately 150 mm diameter semiconductor workpiece and a gap of 6 inches for an approximately 200 mm diameter semiconductor workpiece. The fracture strength of a semiconductor wafer is described in detail with reference to FIGS. 7 and 8 below.

In some examples, the treatment process may be a non-mechanical treatment process. As used herein, a non-mechanical treatment process refers to a process that increases the fracture strength of the semiconductor wafer without requiring physical mechanical contact with a tool surface (e.g., grind wheel, lapping plate, polishing pad, grind disk, or other mechanical surface).

In some examples, the treatment process is performed on the semiconductor wafer prior to performing a surface processing operation, such as a grinding operation, lapping operations, polishing operation, CMP operation, ECMP operation, or other surface processing operation. In this way, high stress processes, such as surface processing operations, may be implemented on the semiconductor wafer with reduced breakage.

In some examples, the treatment process provides a fracture strength of the semiconductor wafer in a range of about 17.5 Newtons or greater. For instance, the treatment process may provide a fracture strength in arrange of about 17.5 Newtons to about 75 Newtons, such as about 25 Newtons to about 75 Newtons, such as about 35 Newtons to about 75 Newtons, such as about 50 Newtons to about 75 Newtons.

In some examples, the treatment process provides an increase fracture strength of about 15% or greater, such as about 25% or greater, such as about 65% or greater, such as about 75% or greater, such as about 100% or greater, such as about 120% or greater, such as about 230% or greater, such as about 300% or greater, such as about 400% or greater. In some examples, the treatment process increases a fracture strength in a range of about 15% to about 430%, such as about 65% to about 430%, such as about 120% to about 430%, such as about 230% to about 430%.

In some examples, the treatment process may include a thermal process, such as a heating process, thermal anneal process, or the like. For instance, the thermal process may include heating the semiconductor wafer to a temperature in a range of about 1000° C. to about 2000° C., such as about 1300° C. to about 1700° C. As used herein, heating a semiconductor wafer or other structure to a specified temperature may refer to heating the ambient environment (e.g., the chamber) in which the semiconductor wafer or other structure is located to the specified temperature and/or may refer to heating the actual semiconductor wafer or other structure to the specified temperature. The thermal process may be implemented, for instance, with any suitable thermal processing apparatus, such as with an inductive heating susceptor, a furnace, a lamp-based heating system, or other suitable system that may heat the temperature of the semiconductor workpiece to a temperature in a range of about 1000° C. to about 2000° C., such as about 1300° C. to about 1700° C.

In some examples, the treatment process may include heating the semiconductor wafer in an environment with an ambient gas. The ambient gas may be an inert gas, such as argon, nitrogen, etc. In some examples, the ambient gas may include an etchant (e.g., hydrogen, silicon, etc.) during the thermal process. For instance, the ambient gas may include a forming gas having a concentration of hydrogen (by weight) of about 7% or less, such as between about 3% to about 7%.

In some examples, the treatment process may include implementing a chemical etching process, such as a wet etch process or a dry etch process. For instance, the treatment process may include implementing a wet etch process at a temperature in a range of about 15° C. to about 100° C. The wet etch process may expose the semiconductor wafer to a wet chemical etchant. The wet chemical etchant may include, for instance, gallium phosphide in some embodiments. However, other suitable wet chemical etchants may be used without deviating from the scope of the present disclosure, such as an inorganic acid (e.g., nitric acid, hydrochloric acid), a hydroxide (e.g., potassium hydroxide).

Aspects of the present disclosure provide a number of technical effects and benefits. For instance, aspects of the present disclosure provide for improved fracture strength of semiconductor wafers, such as silicon carbide semiconductor wafers, after separating or removing the semiconductor wafers from a boule. The improved fracture strength increases the capability of the silicon carbide semiconductor wafer to withstand high stresses during further processing operations or fabrication operations, such as surface processing operations (e.g., grinding, lapping, polishing, CMP, ECMP, etc.). This may lead to reduced breakage during fabrication of silicon carbide semiconductor wafers and/or device fabrication on silicon carbide semiconductor wafers. In some examples, the treatment to increase fracture strength according to examples of the present disclosure increases yield of semiconductor fabrication processes and reduced costs resulting from breakage.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

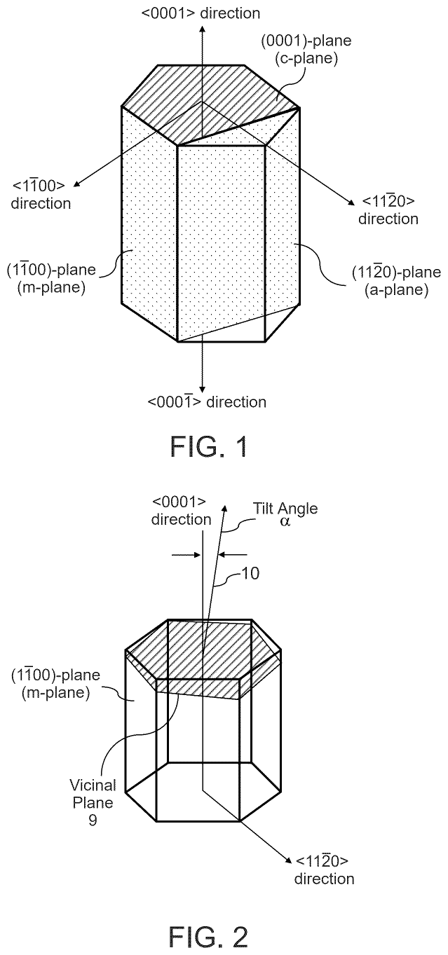

FIG. 1 is a first perspective view crystal plane diagram showing the coordinate system for a hexagonal crystal such as 4H-silicon carbide (“SiC”), in which the c-plane (0001) is perpendicular to both the m-plane (11̅00) and the a-plane (112̅0). The c-plane is perpendicular to the <0001> direction. The m-plane (11̅00) is perpendicular to the <11̅00> direction. The a-plane (112̅0) is perpendicular to the <112̅0> direction. The <0001̅> direction is opposite the <0001> direction.

FIG. 2 is a second perspective view crystal plane diagram for a hexagonal crystal, illustrating a vicinal plane 9 that is non-parallel to the c-plane, wherein a vector 10 (which is normal to the vicinal plane 9) is tilted away from the <0001>direction by a tilt angle α, with the tilt angle α being inclined (slightly) toward the <112̅0> direction.

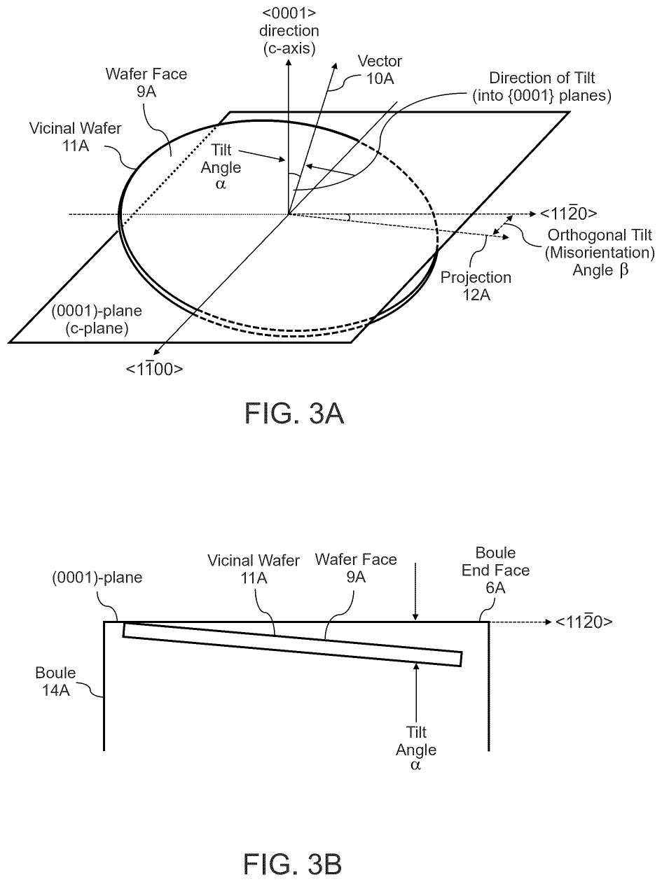

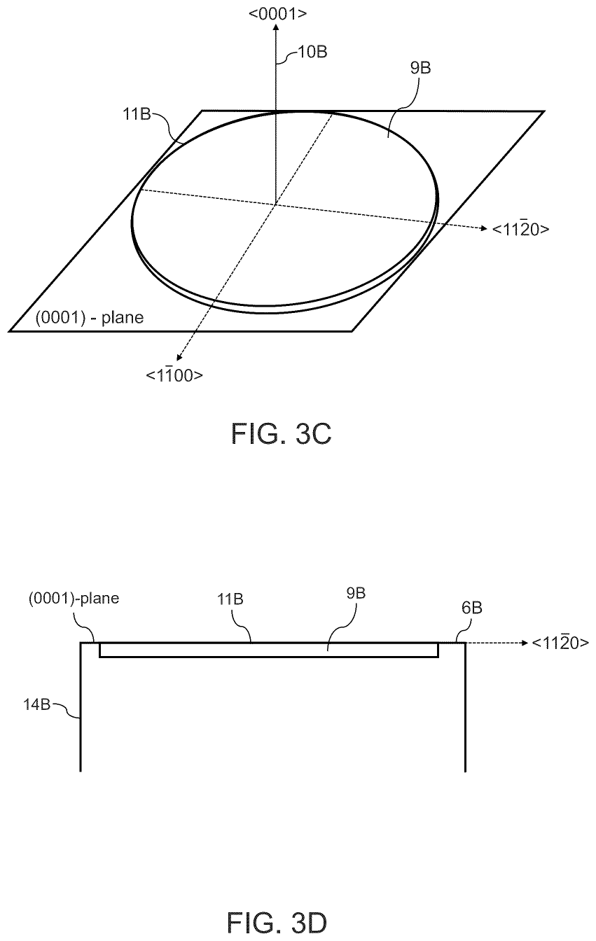

FIG. 3A is a perspective view of a wafer orientation diagram showing orientation of a vicinal wafer 11A relative to the c-plane (0001), in which a vector 10A (which is normal to the wafer face 9A) is tilted away from the <0001> direction by a tilt angle α. An orthogonal tilt (or misorientation angle) β may span between the <112̅0> direction and the projection of vector 10A onto the c-plane.

FIG. 3B is a simplified cross-sectional view of the vicinal wafer 11A superimposed over a portion of a boule 14A (e.g., an on-axis boule having an end face 6A parallel to the (0001) plane) from which the vicinal wafer 11A was defined. FIG. 3B shows that the wafer face 9A of the vicinal wafer 11A is misaligned relative to the (0001) plane by a tilt angle α.

FIG. 3C is a perspective view of wafer orientation diagram showing orientation of an on-axis wafer 11B relative to the c-plane (0001), in which a vector 10B (which is normal to the wafer face 9B) is parallel to the <0001> direction. FIG. 3D is a simplified cross-sectional view of the wafer 11B superimposed over a portion of a boule 14B (e.g., an on-axis boule having an end face 6B parallel to the (0001) plane). FIG. 3D shows that the wafer face 9B of the on axis-wafer 11B is aligned with the (0001) plane.

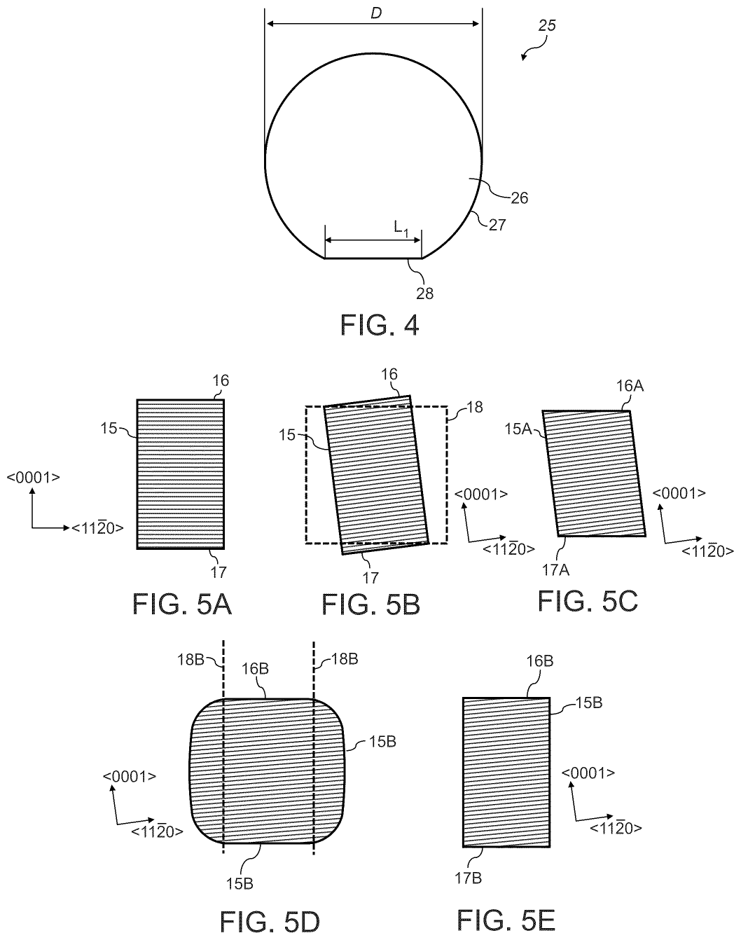

FIG. 4 is a top plan view of an example silicon carbide semiconductor wafer 25 including an upper face 26. The silicon carbide semiconductor wafer 25 may include a surface that is misaligned with (e.g., off-axis at an oblique angle relative to) the c-plane. The silicon carbide semiconductor wafer 25 may be laterally bounded by a generally round edge 27 (having a diameter D) including a primary flat 28 (having a length L₁) that is perpendicular, for instance, to the (112̅0) plane. In some instances, the wafer 25 may include a notch instead of a primary flat.

Methods disclosed herein may be applied to substrates of various crystalline materials, of both single crystal and polycrystalline varieties. In certain embodiments, methods disclosed herein may utilize cubic, hexagonal, and other crystal structures, and may be directed to crystalline materials having on-axis and off-axis crystallographic orientations. In certain embodiments, methods disclosed herein may be applied to semiconductor materials and/or wide bandgap materials. Example materials include, but are not limited to, silicon, gallium arsenide, and diamond.

In certain embodiments, such methods may utilize single crystal semiconductor materials having a hexagonal crystal structure, such as 4H-SiC, 6H-SiC, or Group III-nitride materials (e.g., GaN, AlN, InN, InGaN, AlGaN, or AlInGaN). Various illustrative embodiments described hereinafter mention SiC generally or 4H-SiC specifically, but it is to be appreciated that any suitable crystalline material may be used. Among the various SiC polytypes, the 4H-SiC polytype is particularly attractive for power electronic devices due to its high thermal conductivity, wide bandgap, and isotropic electron mobility. Bulk silicon carbide may be grown on-axis (i.e., with no intentional angular deviation from the c-plane thereof, suitable for forming undoped or semi-insulating material) or off-axis (typically departing from a grown axis such as the c-axis by a non-zero angle, typically in a range of from 0.5 to 10 degrees (or a subrange thereof such as 2 to 6 degrees or another subrange), as may be suitable for forming n-doped or highly conductive material).

Certain embodiments herein may use substrates of doped or undoped silicon carbide, such as silicon carbide boules, which may be grown by physical vapor transport (PVT) or other conventional boule fabrication methods. If doped SiC is used, such doping may render the SiC n-type or semi-insulating in character. In certain embodiments, an n-type silicon carbide boule is intentionally doped with nitrogen. In certain embodiments, an n-type silicon carbide boule includes resistivity values within a range of 0.015 to 0.028 Ohm-centimeters. In certain embodiments, a silicon carbide boule may have resistivity values that vary with vertical position, such that different substrate portions (e.g., wafers) have different resistivity values, which may be due to variation in bulk doping levels during boule growth. In certain embodiments, a silicon carbide boule may have doping levels that vary horizontally, from a higher doping region proximate to a center of the boule to a lower doping level proximate to a lateral edge thereof.

FIGS. 5A and 5C schematically illustrate on-axis and off-axis crystalline substrates in the form of boules that may be utilized with methods disclosed herein. FIG. 5A is a side elevation schematic view of an on-axis boule 15 of crystalline material having first and second end faces 16, 17 that are perpendicular to the c-direction (i.e., <0001> direction for a hexagonal crystal structure material such as 4H-SiC). FIG. 5B is a side elevation schematic view of the boule 15 of FIG. 5A being rotated by four degrees, with a superimposed pattern 18 (shown in dashed lines) for cutting and removing end portions of the boule 15 proximate to the end faces 16, 17. FIG. 5C is a side elevation schematic view of an off-axis boule 15A formed from the boule 15 of FIG. 5B, following removal of end portions to provide new end faces 16A, 17A that are non-perpendicular to the c-direction. Aspects of the present disclosure are applicable to both on-axis boules 15 and/or off-axis boules 15A or other on-axis crystalline materials and/or off-axis crystalline materials.

FIGS. 5D and 5E schematically illustrate off-axis grown boules that may be utilized with methods disclosed herein. FIG. 5D is a side elevation schematic view of an off-axis grown boule 15B of crystalline material (e.g., grown from an off-axis seed material) having first and second end faces 16B and 17B that are non-perpendicular to the c-direction (e.g., <0001> direction for a hexagonal crystal structure material such as 4H-SiC). Portions of the boule 15B may be cut along the superimposed pattern 18B (shown in dashed lines) to provide the off-axis boule 15B shown in FIG. 5E. Off-axis semiconductor wafers may be provided from the off-axis boule 15E by cutting or otherwise removing the wafers from the boule 15B in a manner parallel to the faces 16B, 17B.

Aspects of the present disclosure are directed to providing semiconductor wafers from any suitable boule, such as an on-axis boule, an off-axis boule, an on-axis grown boule, and off-axis grown boule, a boule grown along other directions or axes (e.g., a-axis, c-axis) or other suitable boule.

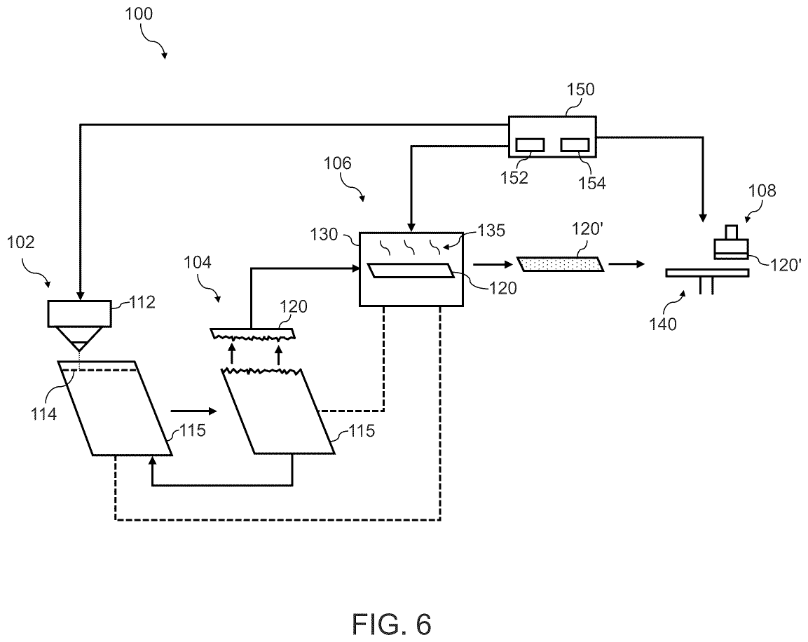

FIG. 6 depicts an overview of an example method 100 according to example embodiments of the present disclosure. FIG. 6 is intended to represent structures for identification and description and is not intended to represent the structures to physical scale. The method 100 depicts operations in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 102, the method 100 may include performing a removal process on a boule 115 (e.g., laser-based removal process, wire saw-based removal process, implant-based removal process). For instance, one or more laser source(s) 112 may be operated according to one or more laser parameters to induce a subsurface laser damage region 114 in the boule 115. The boule 115 may be similar to the boule 15 or the off-axis boule 15A of FIGS. 5A and 5C respectively.

In some examples, the laser source 112 may be operated in accordance with certain laser parameters to induce the subsurface laser damage region 114 in the boule 115. For instance, in certain examples, a laser having a wavelength in a range of about 800 nanometers to about 1100 nanometers may be used to implement the laser-based removal process. Although a wide range of pulse frequencies may be used in certain embodiments, pulse frequencies of 120 kilohertz to 150 kilohertz may be employed in the laser-based removal process. A translation speed in a range of about 500 millimeters per second to about 3000 millimeters per second between a laser source 112 and a boule 115 may be used. However, higher or lower translation stage speeds may be used in certain embodiments with suitable adjustment of laser frequency to maintain desirable laser pulse overlap. Average laser power ranges for forming subsurface laser damage 114 may be in a range of from about 0.5 watts to about 10 watts for silicon carbide. Laser pulse energy may be calculated as power divided by frequency. Laser pulse widths of about 1 nanosecond to about 10 nanoseconds may be used, although other pulse widths may be used in other embodiments.

Referring to FIG. 6 at 104, the method 100 may include separating a semiconductor wafer 120 from the boule 115 along the subsurface laser damage region 114. Separating the wafer 120 from the boule 115 may be performed through a variety of methods. For instance, a mechanical fracturing process, ultrasonic fracturing process, or other fracturing process may be used to fracture and separate the semiconductor wafer 120 from the boule 115. FIG. 6 illustrates a laser-based removal process for purposes of illustration and discussion. Those of ordinary skill in the art, using the disclosures provided herein, will understand that other removal processes may be used without deviating from the scope of the present disclosure, such as saw-based removal processes and/or implant-based removal processes.

In some instances, removing the wafer 120 from the boule 115 may leave rough exposed surfaces on both the semiconductor wafer 120 and the boule 115. For instance, the semiconductor wafer 120 may have an exposed surface 122 with high surface roughness, such as a surface roughness greater than about 65 microns. The exposed surface 122 may include cracks and/or features with sharp tips. These features may act as stress concentrators that reduce a fracture strength of the semiconductor wafer.

Aspects of the present disclosure are directed to implementing a treatment process to increase fracture strength of the semiconductor wafer 120 after removal from the boule 115. For instance at 106, the semiconductor wafer 120 may be provided to a treatment chamber 130. The treatment chamber 130 may be operable to implement a treatment process 135 on the semiconductor wafer 120. Example treatment chambers are discussed in detail below.

In some examples, the treatment process 135 may be a non-mechanical treatment process. As used herein, a non-mechanical treatment process refers to a process that increases the fracture strength of the semiconductor wafer without requiring physical mechanical contact with a tool surface (e.g., grind wheel, lapping plate, polishing pad, grind disk, or other mechanical surface).

In some examples, the treatment process 135 may include a thermal process, such as a heating process, thermal anneal process, or the like. For instance, the thermal process may include heating the semiconductor wafer to a temperature in a range of about 1000° C. to about 2000° C., such as about 1300° C. to about 1700° C. The thermal process may be implemented, for instance, with any suitable thermal processing apparatus, such as with an inductive heating susceptor, a furnace, a lamp-based heating system, or other suitable system that may heat the temperature of the semiconductor workpiece to a temperature in a range of about 1000° C. to about 2000°° C., such as about 1300° C. to about 1700° C.

In some examples, the treatment process 135 may include heating the semiconductor wafer in an environment with an ambient gas. The ambient gas may be an inert gas, such as argon, nitrogen, etc. In some examples, the ambient gas may include an etchant (e.g., hydrogen, silicon, etc.) during the thermal process. For instance, the ambient gas may include a forming gas having a concentration of hydrogen (by weight) of about 7% or less, such as between about 3% to about 7%.

In some examples, the treatment process 135 may include implementing a chemical etching process, such as a wet etch process or a dry etch process. For instance, the treatment process 135 may include implementing a wet etch process at a temperature in a range of about 15° C. to about 100° C. The wet etch process may expose the semiconductor wafer to a wet chemical etchant. The wet chemical etchant may include, for instance, gallium phosphide in some embodiments. However, other suitable wet chemical etchants may be used without deviating from the scope of the present disclosure, such as an inorganic acid (e.g., nitric acid, hydrochloric acid), a hydroxide (e.g., potassium hydroxide).

The treatment process 135 results in a treated semiconductor wafer 120′. The treated semiconductor wafer 120′ will have an increased fracture strength relative to prior to performing the treatment process. In some examples, the treatment process provides a fracture strength of the semiconductor wafer in a range of about 17.5 Newtons or greater. For instance, the treatment process may provide a fracture strength in a range of about 17.5 Newtons to about 75 Newtons, such as about 25 Newtons to about 75 Newtons, such as about 35 Newtons to about 75 Newtons, such as about 50 Newtons to about 75 Newtons.

FIG. 7-8 depict example determination of fracture strength according to examples of the present disclosure. FIG. 7 depicts a cross-sectional view of a testing apparatus 200 for determining fracture strength. FIG. 8 depicts a plan view of a testing apparatus 200 for determining fracture strength. As illustrated, a semiconductor wafer 120 (e.g., silicon carbide semiconductor wafer) is placed on a two rectangular workpiece supports 210, 212 that are spaced apart a distance D. The distance D is 4 inches for an approximately 150 mm diameter semiconductor workpiece and a gap of 6 inches for an approximately 200 mm diameter semiconductor workpiece. In some examples the distance D may be greater in the event the diameter of the wafer is greater. In some examples, the distance D may be less in the event the diameter of the wafer is less. In some examples, a ratio of the distance D to the diameter is approximately 0.5 to about 0.8, such as about 0.7. In some examples, the rectangular workpiece supports 210, 212 may each have a width W1. The width W1 may be 1 inch.

The testing apparatus 200 includes a test head 220. The test head 220 may have a rounded tip for contact with the semiconductor wafer 120 during performance of the test.

The test head 220 may be driven in a direction towards and against the semiconductor wafer 120 by an actuator 222. In some examples, the actuator 222 may be, for instance, a ball screw. However, other suita00ble actuators (e.g., linear actuators) may be used without deviating from the scope of the present disclosure. The distance the test head 220 is driven may be measured by an encoder or other suitable sensor that may provide data indicative of the distance the test head 220 is driven. The testing apparatus 200 may include a load cell sensor or other suitable sensor configured to measure force applied to the semiconductor wafer during a fracture strength test.

The testing apparatus 200 may implement a fracture strength test by driving the test head 220 against the semiconductor wafer along an axis 225 that is halfway between the workpiece support 210, 212 such that the test head 220 is applied to a center portion of the semiconductor wafer 120. The distance the test head 220 is driven may be measured. The displacement of the semiconductor wafer 120 may be measured during the fracture strength test. The force applied to the semiconductor wafer 120 with the test head 220 may be measured during the fracture strength test. The fracture strength, as used herein, refers to the force that may be applied to the semiconductor wafer 120 before breaking the semiconductor wafer 120 during a fracture strength test with the testing system of FIG. 7-8. The magnitude of the force (in Newtons or other suitable unit of force) may be the fracture strength.

Referring back to FIG. 6, after performing the treatment process 135 at 108, the treated semiconductor wafer 120′ may be provided for further processing operations, such as surface processing operations. For instance, the treated semiconductor wafer 120′ may be provided to a surface processing apparatus 140. The surface processing apparatus 140 may be, for instance, a grinding system, lapping system, polishing system, CMP system, ECMP system, or other suitable system used to perform a surface processing operation on the treated semiconductor wafer 120′.

Aspects of the present disclosure are directed to using a treatment process 135 on a semiconductor wafer 120 for purposes of illustration and discussion. Those of ordinary skill in the art, using the disclosures provided herein, will understand that treatment processes according to examples of the present disclosure may be implemented on other semiconductor workpieces without deviating from the scope of the present disclosure. For instance, as illustrated by the dashed lines in FIG. 6, the treatment process 135 may be performed on the boule 115 prior to removal of subsequent semiconductor wafers.

As illustrated in FIG. 6, aspects of the removal process, treatment process, and/or surface processing operations may be controlled by control circuitry including one or more control devices, such as a controller 150. The controller 150 may include one or more processors 152 and one or more memory devices 154. The one or more memory devices 154 may store computer-readable instructions that when executed by the one or more processors 152 cause the one or more processors 152 to perform one or more control functions, such as any of the functions described herein. The controller 150 may be in communication with various other aspects or components through one or more wired and/or wireless control links. The controller 150 may send control signals to the various components (e.g., the laser source 112, the treatment chamber 130, the surface processing apparatus 140) to implement operations on a semiconductor workpiece, such as semiconductor wafer 120 or boule 115.

FIG. 9 depicts a cross-section view of one example treatment chamber 300 that may be operable to implement a treatment process for increasing fracture strength of a semiconductor wafer or other semiconductor workpiece according to examples of the present disclosure. The treatment chamber 300 includes a susceptor 312. The susceptor 312 may be heated by an inductive technique (such as radio frequency) using the electrodes 313 on the exterior of the chamber 300. A semiconductor workpiece 120 rests on the susceptor 312 so that as the radiation from the electrodes 313 heats the susceptor 312, the susceptor heats the semiconductor wafer 120. FIG. 9 depicts processing a single semiconductor wafer 120 for purposes of illustration and discussion. In some examples, the chamber 300 may be configured for batch processing of multiple semiconductor wafers or workpieces at the same time.

The treatment chamber 300 includes one or more gas sources 315 operable to flow a process gas as an ambient gas during the treatment process. The process gas may be provided to the treatment chamber 300 through a suitable gas delivery system (e.g., including one or more gas flow tubes, passageways, plenums, nozzles, showerheads, ports, etc.). The process gas may be exhausted from the treatment chamber through a suitable exhaust system 321.

In some examples, the treatment chamber 300 may implement a treatment process to increase a fracture strength of the semiconductor wafer 120. The treatment process may include heating the semiconductor wafer 120 (e.g., with the susceptor 312) to a temperature in a range of about 1000° C. to about 2000° C., such as about 1300° C. to about 1700° C. In some examples, ambient gas (e.g., with no etchant) may be provided to the treatment chamber 300. The ambient gas may be an inert gas. The inert gas may be, for instance, argon, or other suitable inert gas (e.g., nitrogen). The treatment process may have a process period in a range of 5 minutes to about 25 minutes, such as about 10 minutes to about 20 minutes. However, in some embodiments, the ambient gas may include an etchant (e.g., hydrogen, silicon). For instance, the ambient gas may include a forming gas having a concentration of hydrogen (by weight) of less than about 7%, such as between about 3% to about 7%.

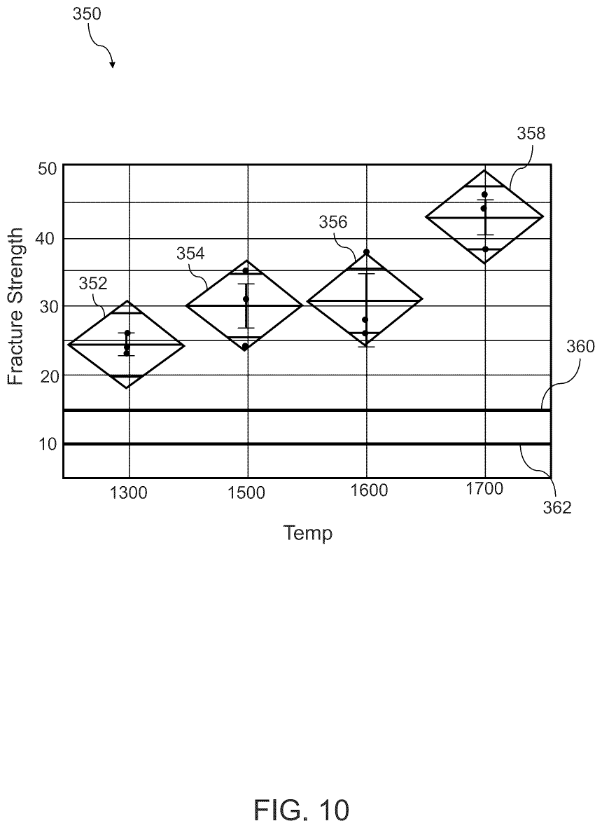

FIG. 10 depicts example results 350 from an example treatment process according to example embodiments of the present disclosure. FIG. 10 plots fracture strength (as determined in accordance with the fracture strength test discussed with reference to FIGS. 7-8) on the vertical axis. The results 350 include four fracture strength distributions 352, 354, 356, and 358.

Fracture strength distribution 352 is associated with heating approximately 150 mm diameter silicon carbide semiconductor wafers to 1300° C. (e.g., using treatment chamber 300) in an inert ambient gas for a process period of approximately 10 minutes. Fracture strength distribution 354 is associated with heating 150 mm diameter silicon carbide semiconductor wafers to 1300° C. (e.g., using treatment chamber 300) in an inert ambient gas for a process period of approximately 10 minutes. Fracture strength distribution 356 is associated with heating 150 mm diameter silicon carbide semiconductor wafers to 1500° C. (e.g., using treatment chamber 300) in an inert ambient gas for a process period of approximately 10 minutes. Fracture strength distribution 358 is associated with heating 150 mm diameter silicon carbide semiconductor wafers to 1700° C. (e.g., using treatment chamber 300) in an inert ambient gas for a process period of approximately 10 minutes.

The fracture strength range between lines 360 and 362 (e.g., between about 10Newtons and about 15 Newtons) represents the fracture strength of untreated 150 mm silicon carbide semiconductor wafers after being removed from a boule. As demonstrated by the results 350 of FIG. 10, treating the semiconductor wafers by heating may result in increased fracture strength, such as about 15% or greater, such as about 25% or greater, such as about 65% or greater, such as about 75% or greater, such as about 100% or greater, such as about 120% or greater, such as about 230% or greater, such as about 300% or greater, such as about 400% or greater. In some examples, the treatment process increases a fracture strength in a range of about 15% to about 430%, such as about 65% to about 430%, such as about 120% to about 430%, such as about 230% to about 430%.

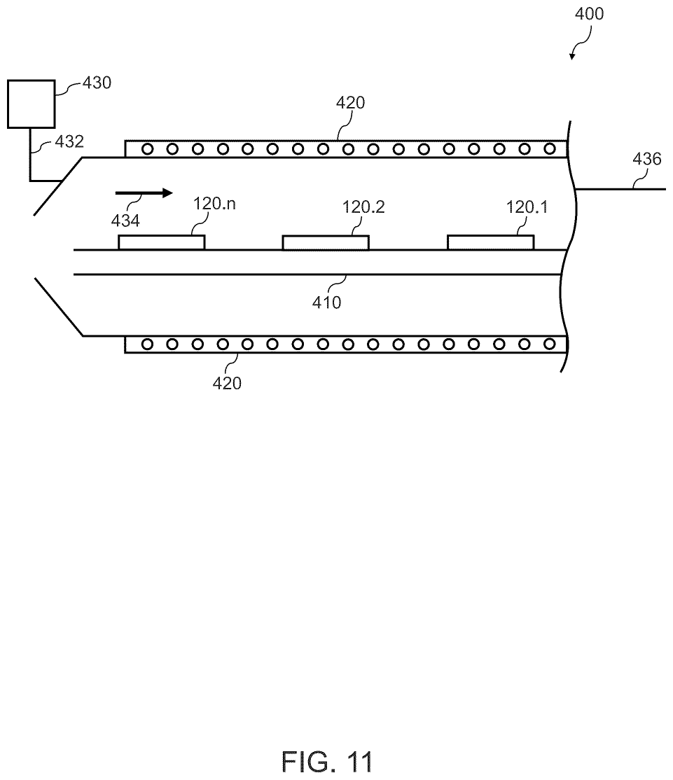

FIG. 11 depicts a cross-section view of one example treatment chamber 400 that may be operable to implement a treatment process for increasing fracture strength of a semiconductor wafer or other semiconductor workpiece according to examples of the present disclosure. The treatment chamber 400 is a furnace that includes heating elements 420 (e.g., resistive heating elements) about the treatment chamber 400. A workpiece holder 410 may be operable to hold one or more semiconductor workpieces, such as a plurality of semiconductor wafers 120.1, 120.2, . . . 120.n. FIG. 11 depicts processing a plurality of semiconductor wafers 120.1, 120.2, . . . 120.n for purposes of illustration and discussion. In some examples, the chamber 400 may be configured for single wafer processing without deviating from the scope of the present disclosure.

The treatment chamber 400 includes one or more gas sources 430 operable to flow a process gas as an ambient gas 434 during the treatment process. The process gas may be provided to the treatment chamber 400 through a suitable gas delivery system (e.g., including one or more gas flow tubes, passageways, plenums, nozzles, showerheads, ports, etc.). The process gas may be exhausted from the treatment chamber through a suitable exhaust system 436.

In some examples, the treatment chamber 400 may implement a treatment process to increase a fracture strength of the semiconductor wafer 120. The treatment process may include heating the semiconductor wafer 120 (e.g., with the heating elements 420) to a temperature in a range of about 1000° C. to about 2000° C., such as about 1300° C. to about 1700° C. In some examples, ambient gas (e.g., with no etchant) may be provided to the treatment chamber 300. The ambient gas may be an inert gas. The inert gas may be, for instance, argon, or other suitable inert gas (e.g., nitrogen). The treatment process may have a process period in a range of 5minutes to about 25 minutes, such as about 10 minutes to about 20 minutes. However, in some embodiments, the ambient gas may include an etchant (e.g., hydrogen, silicon). For instance, the ambient gas may include a forming gas having a concentration of hydrogen (by weight) of less than about 7%, such as between about 3% and about 7%.

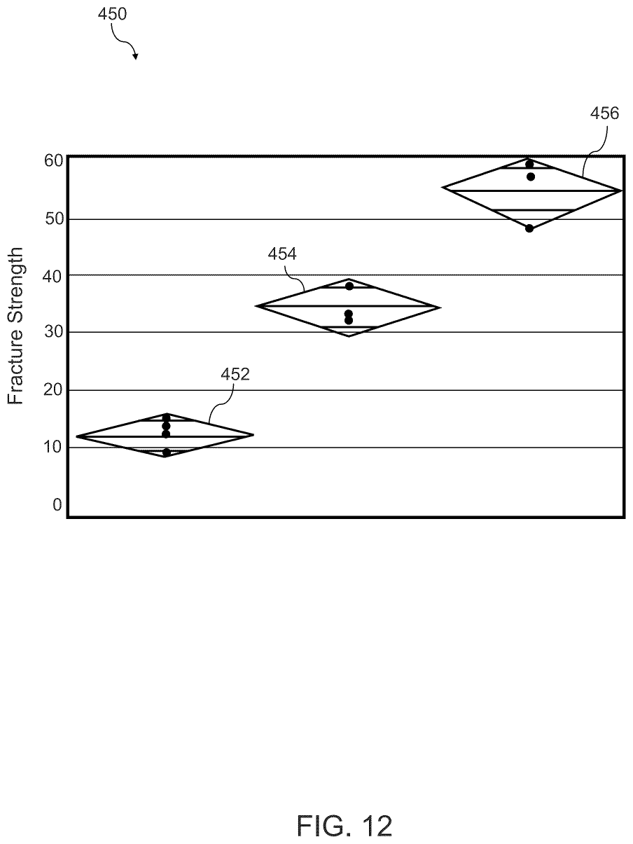

FIG. 12 depicts example results 450 from an example treatment process according to example embodiments of the present disclosure. FIG. 12 plots fracture strength (as determined in accordance with the fracture strength test discussed with reference to FIGS. 7-8) on the vertical axis. The results 450 include three fracture strength distributions 452, 454, and 456.

Fracture strength distribution 452 is associated with approximately 150 mm silicon carbide wafers removed from a boule with no treatment process. Fracture strength distribution 454 is associated with heating 150 mm diameter silicon carbide semiconductor wafers to 1700° C. (e.g., using treatment chamber 400) in an inert ambient gas (e.g., argon) for a process period of approximately 20 minutes. Fracture strength distribution 356 is associated with heating 150 mm diameter silicon carbide semiconductor wafers to 1700° C. (e.g., using treatment chamber 400) in forming gas (e.g., less than about 7% hydrogen (by weight), such as between 3% to about 7% hydrogen (by weight)) for a process period of approximately 20 minutes.

As demonstrated by the results 450, heating the semiconductor wafer in an inert ambient gas increases the fracture strength of the semiconductor wafers (relative to no treatment). Heating the semiconductor wafer in an ambient gas with an etchant (e.g., a forming gas) results in a significant increase in fracture strength, such as about 15% or greater, such as about 25% or greater, such as about 65% or greater, such as about 75% or greater, such as about 100% or greater, such as about 120% or greater, such as about 230% or greater, such as about 300% or greater, such as about 400% or greater. In some examples, the treatment process increases a fracture strength in a range of about 15% to about 430%, such as about 65% to about 430%, such as about 120% to about 430%, such as about 230% to about 430%.

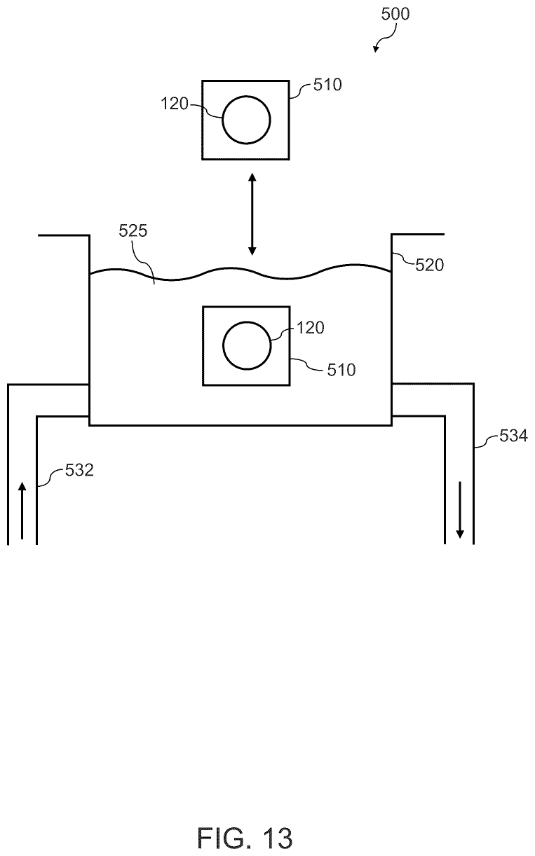

FIG. 13 depicts a cross-section view of one example treatment chamber 500 that may be operable to implement a treatment process for increasing fracture strength of a semiconductor wafer or other semiconductor workpiece according to examples of the present disclosure. The treatment chamber 500 is a wet etch treatment chamber. A workpiece holder 510 may be operable to hold one or more semiconductor workpieces, such as semiconductor wafer 120. FIG. 13 depicts processing a single semiconductor wafer 120 for purposes of illustration and discussion. In some examples, the chamber 500 may be configured for batch processing of multiple semiconductor wafers or workpieces at the same time.

The workpiece holder 510 may be configured to provide the semiconductor wafer 120 into a wet etchant bath 520 so that the semiconductor wafer is exposed to a wet chemical etchant 525. Other suitable techniques or systems for exposing the semiconductor wafer 120 to a wet chemical etchant 525 may be used (e.g., a spray system) without deviating from the scope of the present disclosure. The wet chemical etchant 525 may be provided into (e.g., flowed into) the wet etchant bath 520 through an inlet 532 and may be provided from the wet etchant bath (e.g., flowed out of) through an outlet 534.

In some examples, the wet chemical etchant 525 may include, for instance, gallium phosphide. However, other suitable wet chemical etchants may be used without deviating from the scope of the present disclosure, such as an inorganic acid (e.g., nitric acid, hydrochloric acid), a hydroxide (e.g., potassium hydroxide).

In some examples, the treatment chamber 500 may implement a treatment process to increase a fracture strength of the semiconductor wafer 120. For instance, the treatment chamber 500 may implement a wet etch process at a temperature in a range of about 15° C. to about 100° C. The wet etch process may expose the semiconductor wafer to a wet chemical etchant 525. The wet chemical etchant 525 may include, for instance, gallium phosphide in some embodiments. However, other suitable wet chemical etchants may be used without deviating from the scope of the present disclosure, such as an inorganic acid (e.g., nitric acid, hydrochloric acid), a hydroxide (e.g., potassium hydroxide).

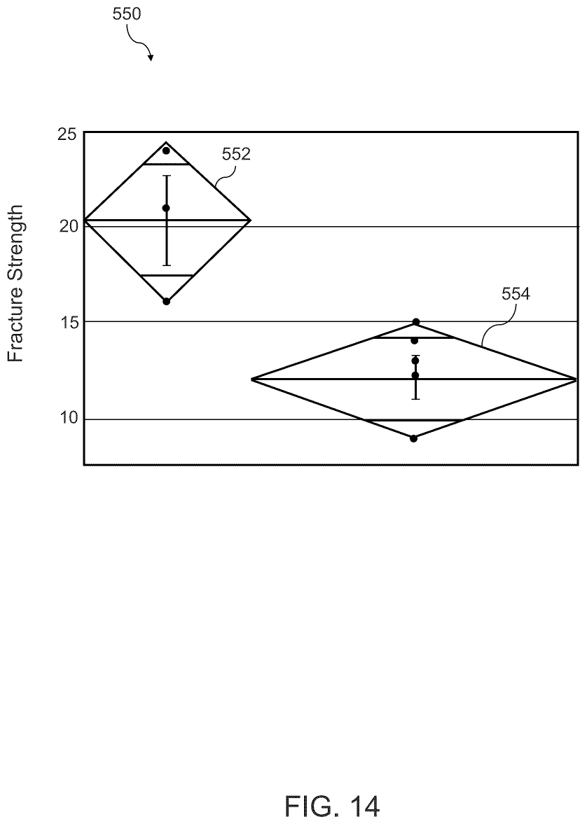

FIG. 14 depicts example results 550 from an example treatment process according to example embodiments of the present disclosure. FIG. 14 plots fracture strength (as determined in accordance with the fracture strength test discussed with reference to FIGS. 7-8) on the vertical axis. The results 550 include two fracture strength distributions 552 and 554.

Fracture strength distribution 554 is associated with approximately 150 mm silicon carbide wafers removed from a boule with no treatment process. Fracture strength distribution 552 is associated with providing 150 mm diameter silicon carbide semiconductor wafers in a wet chemical etchant including gallium phosphide at approximately 85° C. for approximately 80 minutes. As demonstrated by the results 550, treating the semiconductor wafers with a wet chemical etchant (e.g., gallium phosphide) increases the fracture strength of the silicon carbide semiconductor wafers.

Other suitable treatment chambers may be used to implement a treatment process without deviating from the scope of the present disclosure. For instance, in some examples, a treatment process may include a dry etch process that exposes a semiconductor workpiece (e.g., silicon carbide semiconductor wafer) to species generated in a plasma.

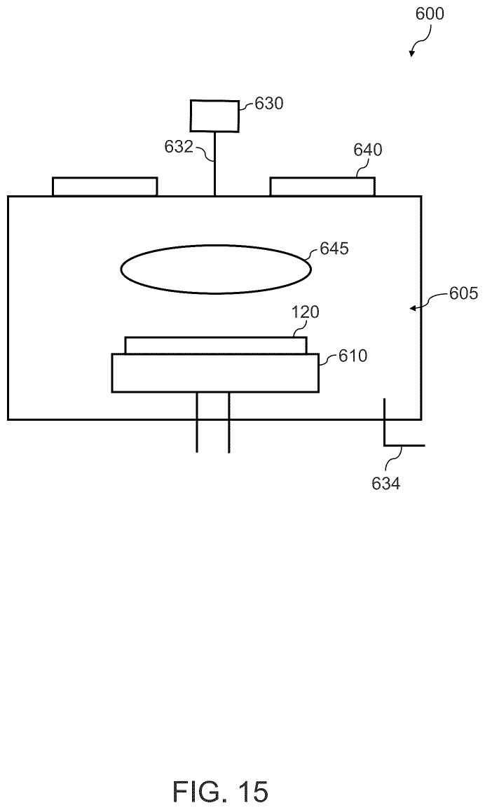

FIG. 15 depicts a plasma-based processing process system 600 operable to provide a treatment process on a semiconductor workpiece according to examples of the present disclosure. The system 600 includes a chamber 605, a workpiece support 610, a process gas source 630, and a plasma source 640. The workpiece support 610 may include a chuck (e.g., electrostatic chuck) or other mechanism to hold the semiconductor wafer 120 in place during a treatment process. The process gas source 630 may be operable to deliver a process gas to the chamber 605, for instance, using a gas delivery outlet 632 (e.g., showerhead). The plasma source 640 may be configured to induce a plasma 645 in the process gas. The process gas may be exhausted from the chamber 605 through exhaust system 634. The plasma 645 is used to treat the semiconductor wafer 120. The plasma source 640 may be, for instance, one or more of an inductively coupled plasma source, capacitively coupled plasma source, microwave plasma source, transformer coupled plasma source, helicon wave plasma source, etc. or combination of any of the foregoing sources.

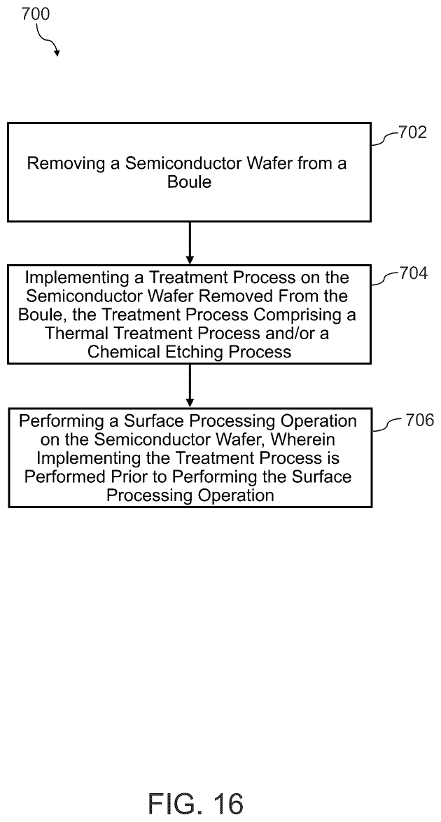

FIG. 16 depicts a flow chart diagram of an example method 700 according to example aspects of the present disclosure. The method 700 includes operations illustrated in a particular order for purposes of illustration and discussion. Those of ordinary skill in the art, using the disclosures provided herein, will understand that the various steps or operations of any of the method provided in this disclosure may be adapted, rearranged, omitted, include steps not illustrated, and/or modified in various ways without deviating from the scope of the present disclosure.

At 702, the method 700 includes removing a semiconductor wafer (e.g., wide bandgap semiconductor wafer, such as a silicon carbide semiconductor wafer) from a boule using a removal process. In some embodiments, the boule may be a silicon carbide boule and, therefore, the semiconductor wafer may be a silicon carbide semiconductor wafer. In some examples, the removal process may be, for instance, a wire saw based removal process, a laser-based removal process, or an implant-based removal process.

At 704, the method 700 includes implementing a treatment process on the semiconductor wafer removed from the boule. In some examples, the treatment process may be a thermal treatment process and/or a chemical treatment process. The treatment process is to increase the fracture strength of the semiconductor wafer. The treatment process may, in some implementations, increase fracture strength by rounding sharp tips on features (e.g., cracks, voids, etc.) on the surface of the semiconductor wafer resulting from the removal process. In some examples, the treatment process may reduce a height of one or more peak topographical area on a surface of the semiconductor wafer. In some examples, the treatment process may reduce a surface roughness (e.g., Sz (maximum height) surface roughness) on a surface of the semiconductor wafer.

The fracture strength of the semiconductor wafer may be determined, for instance, by placing the semiconductor wafer on two support structures spaced 4 inches apart for an approximately 150 mm diameter semiconductor workpiece and a gap of 6 inches for an approximately 200 mm diameter semiconductor workpiece and providing a force on the semiconductor wafer at a location halfway between the two support structures. The fracture strength corresponds to the greatest force provided to the semiconductor wafer without breaking. A discussion of determination of fracture strength is provided with reference to FIGS. 7 and 8.

In some examples, implementing the treatment process provides a fracture strength of about 17.5 Newtons or greater. For instance, the treatment process may provide a fracture strength in a range of about 17.5 Newtons to about 75 Newtons, such as about 25 Newtons to about 75 Newtons, such as about 35 Newtons to about 75 Newtons, such as about 50 Newtons to about 75 Newtons.

In some examples, the treatment process may be a non-mechanical treatment process. For instance, in some examples, the treatment process may include a thermal process, such as a heating process, thermal anneal process, or the like. For instance, the thermal process may include heating the semiconductor wafer to a temperature in a range of about 1000° C. to about 2000° C., such as about 1300° C. to about 1700° C. The thermal process may be implemented, for instance, with any suitable thermal processing apparatus, such as with an inductive heating susceptor, a furnace, a lamp-based heating system, or other suitable system that may heat the temperature of the semiconductor workpiece to a temperature in a range of about 1000° C. to about 2000° C., such as about 1300° C. to about 1700° C.

In some examples, the treatment process may include heating the semiconductor wafer in an environment with an ambient gas. The ambient gas may be an inert gas, such as argon, nitrogen, etc. In some examples, the ambient gas may include an etchant (e.g., hydrogen, silicon, etc.) during the thermal process. For instance, the ambient gas may include a forming gas having a concentration of hydrogen (by weight) of about 7% or less, such as between about 3% to about 7%.

In some examples, the treatment process may include implementing a chemical etching process, such as a wet etch process or a dry etch process. For instance, the treatment process may include implementing a wet etch process at a temperature in a range of about 15° C. to about 100° C. The wet etch process may expose the semiconductor wafer to a wet chemical etchant. The wet chemical etchant may include, for instance, gallium phosphide in some embodiments. However, other suitable wet chemical etchants may be used without deviating from the scope of the present disclosure, such as an inorganic acid (e.g., nitric acid, hydrochloric acid), a hydroxide (e.g., potassium hydroxide).

At 706, the method 700 includes performing a surface processing operation on the semiconductor wafer. In some examples, the surface processing operation may include one or more of a grinding operation, lapping operation, polishing operation, chemical mechanical polishing operation, or electrochemical mechanical polishing operation.

In some examples, the surface processing operation is performed after the treatment process such that the treatment process is performed prior to performing the surface processing operation. In this way, the treatment process may increase the fracture strength of the semiconductor wafer so that the semiconductor wafer may withstand higher stresses during the surface processing operation with reduced likelihood of breakage.

Example aspects of the present disclosure are set forth below. Any of the below features or examples may be used in combination with any of the embodiments or features provided in the present disclosure.

In an aspect, an example method of processing a crystalline semiconductor workpiece includes removing a semiconductor wafer from a boule. The method includes implementing a treatment process on the semiconductor wafer removed from the boule. The treatment process includes a thermal treatment process or a chemical etching process. The treatment process provides a fracture strength of the semiconductor wafer in a range of about 17.5 Newtons or greater.

In some implementations of the example method, the fracture strength is determined by placing the semiconductor wafer on two support structures and providing a force on the semiconductor wafer at a location halfway between the two support structures, wherein the fracture strength corresponds to the greatest force provided to the semiconductor wafer without breaking.

In some implementations of the example method, the treatment process provides a fracture strength in a range of about 25 Newtons to about 75 Newtons.

In some implementations of the example method, the treatment process provides a fracture strength in a range of about 35 Newtons to about 75 Newtons.

In some implementations of the example method, the treatment process provides a fracture strength of in a range of about 50 Newtons to about 75 Newtons.

In some implementations of the example method, the treatment process is a non-mechanical treatment process.

In some implementations of the example method, the method includes performing a surface processing operation on the semiconductor wafer, wherein implementing the treatment process is performed prior to performing the surface processing operation.

In some implementations of the example method, the surface processing operation includes one or more of a grinding operation, lapping operation, polishing operation, chemical mechanical polishing operation, or electrochemical mechanical polishing operation.

In some implementations of the example method, the treatment processing includes a thermal anneal process, wherein the thermal anneal process includes heating the semiconductor wafer.

In some implementations of the example method, heating the semiconductor wafer includes heating the semiconductor wafer at a temperature in a range of about 1000° C. to about 2000° C.

In some implementations of the example method, heating the semiconductor wafer includes heating the semiconductor wafer at a temperature in a range of about 1300° C. to about 1700° C.

In some implementations of the example method, heating the semiconductor wafer includes heating the semiconductor wafer in an ambient gas.

In some implementations of the example method, the ambient gas is an inert gas.

In some implementations of the example method the inert gas comprises argon.

In some implementations of the example method, the ambient gas comprises an etchant.

In some implementations of the example method, the etchant includes hydrogen.

In some implementations of the example method, the etchant includes silicon.

In some implementations of the example method, the ambient gas includes a forming gas, the forming gas having a concentration of hydrogen by weight of about 7% or less.

In some implementations of the example method, heating the semiconductor wafer includes heating the semiconductor wafer for a process period in a range of about 5 minutes to about 25 minutes.

In some implementations of the example method, heating the semiconductor wafer includes heating the semiconductor wafer for a process period in a range of about 10 minutes to about 20 minutes.

In some implementations of the example method, the treatment process includes a wet etch process, the wet etch process comprising exposing the semiconductor wafer to a wet chemical etchant.

In some implementations of the example method, exposing the semiconductor wafer to a wet chemical etchant includes exposing the semiconductor wafer to a wet chemical etchant at a temperature in a range of about 15° C. to about 100° C.

In some implementations of the example method, the wet chemical etchant includes gallium phosphide.

In some implementations of the example method, the wet chemical etchant includes an inorganic acid.

In some implementations of the example method, the inorganic acid includes one or more of nitric acid or hydrochloric acid.

In some implementations of the example method, the wet chemical etchant includes an hydroxide.

In some implementations of the example method, the hydroxide includes potassium hydroxide.

In some implementations of the example method, the treatment process includes a dry etch process, the dry etch process comprising exposing the semiconductor wafer to one or more species generated in a plasma.

In some implementations of the example method, the treatment process reduces a height of one or more peak topographical areas on a surface of the semiconductor wafer.

In some implementations of the example method, the treatment process reduces a surface roughness Sz of the semiconductor wafer.

In some implementations of the example method, removing a semiconductor wafer from a boule includes implementing a saw-based removal process, a laser-based removal process, or an implanted species-based removal process.

In some implementations of the example method, the semiconductor wafer includes silicon carbide.

In an aspect, the present disclosure provides an example system. In some implementations, the example system includes a treatment chamber. In some implementations, the example system includes a workpiece holder operable to hold a silicon carbide semiconductor wafer removed on from a boule. In some implementations, the example system includes control circuitry configured to implement a non-mechanical treatment process on the semiconductor wafer to increase a fracture strength of the semiconductor wafer.

In some implementations of the example system, the non-mechanical treatment process includes implementing a thermal anneal process on the semiconductor wafer, the thermal anneal process heating the semiconductor wafer in the treatment chamber at a temperature in a range of about 1000° C. to about 2000° C.

In some implementations of the example system, the non-mechanical treatment process includes providing an ambient gas from a gas source into the treatment chamber, wherein heating the semiconductor wafer includes heating the semiconductor wafer in the ambient gas.

In some implementations of the example system, the ambient gas is an inert gas.

In some implementations of the example system, the ambient gas includes an etchant.

In some implementations of the example system, the etchant includes hydrogen or silicon.

In some implementations of the example system, the ambient gas includes a forming gas, the forming gas, the forming gas having a concentration of hydrogen by weight of about 7% or less.

In some implementations of the example system, the non-mechanical treatment process includes exposing the semiconductor wafer to a wet chemical etchant from an etchant source in the treatment chamber.

In some implementations of the example system, the wet chemical etchant includes one or more of gallium phosphide, nitric acid, hydrochloric acid, or potassium hydroxide.

In some implementations of the example system, the non-mechanical treatment process includes exposing the semiconductor wafer in the treatment chamber to one or more species generated by a plasma.

In some implementations of the example system, the control circuitry is configured to control a workpiece handling robot to remove the semiconductor wafer from the treatment chamber after the treatment process.

In some implementations of the example system, the control circuitry is programmed to implement a non-mechanical treatment process.

In an aspect, the present disclosure provides an example method for treating a silicon carbide semiconductor workpiece to increase a fracture strength of the semiconductor workpiece. In some implementations, the example method includes heating the silicon carbide semiconductor workpiece at a temperature in a range of about 1000° C. to about 2000° C.

In some implementations of the example method, heating the silicon carbide semiconductor workpiece includes heating the silicon carbide semiconductor workpiece at a temperature in a range of about 1300° C. to about 2000° C.

In some implementations of the example method, heating the silicon carbide semiconductor workpiece includes heating the silicon carbide semiconductor workpiece in an ambient gas.

In some implementations of the example method, the ambient gas is an inert gas.

In some implementations of the example method, the ambient gas includes an etchant.

In some implementations of the example method, the etchant includes hydrogen or silicon.

In some implementations of the example method, the ambient gas includes a forming gas, the forming gas, the forming gas having a concentration of hydrogen by weight of about 7% or less.

In some implementations of the example method, heating the silicon carbide semiconductor workpiece includes heating the silicon carbide semiconductor workpiece for a process period in a range of about 5 minutes to about 25 minutes.

In some implementations of the example method, heating the silicon carbide semiconductor workpiece includes heating the silicon carbide semiconductor workpiece for a process period in a range of about 10 minutes to about 20 minutes.

In some implementations of the example method, heating the silicon carbide semiconductor workpiece provides a fracture strength in a range of about 25 Newtons to about 75 Newtons.

In some implementations of the example method, the fracture strength is determined by placing the silicon carbide semiconductor workpiece on two support structures and providing a force on the silicon carbide semiconductor workpiece at a location halfway between the two support structures, wherein the fracture strength corresponds to the greatest force provided to the silicon carbide semiconductor workpiece without breaking.

In some implementations of the example method, heating the silicon carbide semiconductor workpiece provides a fracture strength in a range of about 35 Newtons to about 75 Newtons.

In some implementations of the example method, wherein heating the silicon carbide semiconductor workpiece provides a fracture strength in a range of about 50 Newtons to about 75 Newtons.

In some implementations of the example method, wherein the method further comprises performing a mechanical surface processing operation on the silicon carbide semiconductor workpiece after heating the silicon carbide semiconductor workpiece.

In some implementations of the example method, the mechanical surface processing operation includes one or more of a grinding operation, lapping operation, polishing operation, chemical mechanical polishing operation, or electrochemical mechanical polishing operation.

In an aspect, the present disclosure provides an example method for treating a silicon carbide semiconductor workpiece to increase a fracture strength of the semiconductor workpiece. In some implementations, the example method includes exposing the silicon carbide semiconductor workpiece to a wet chemical etchant at a temperature in range of about at a temperature in a range of about 15° C. to about 100° C.

In some implementations of the example method, the wet chemical etchant includes gallium phosphide.

In some implementations of the example method, the wet chemical etchant includes an inorganic acid.

In some implementations of the example method, the inorganic acid includes one or more of nitric acid or hydrochloric acid.

In some implementations of the example method, the wet chemical etchant includes an hydroxide.

In some implementations of the example method, the hydroxide includes potassium hydroxide.

In some implementations of the example method, exposing the silicon carbide semiconductor workpiece provides a fracture strength in a range of about 17.5 Newtons to about 25 Newtons.

In some implementations of the example method, the fracture strength is determined by placing the silicon carbide semiconductor workpiece on two support structures and providing a force on the silicon carbide semiconductor workpiece at a location halfway between the two support structures, wherein the fracture strength corresponds to the greatest force provided to the silicon carbide semiconductor workpiece without breaking.

In an aspect, the present disclosure provides an example method. The method includes removing a semiconductor wafer from a boule. The method includes implementing a treatment process on the semiconductor wafer removed from the boule, the treatment process comprising a thermal treatment process or a chemical etching process; and wherein the treatment process increases a fracture strength of the semiconductor workpiece by about 15% or greater.

In some implementations of the example method, wherein the fracture strength is determined by placing the semiconductor wafer on two support structures and providing a force on the semiconductor wafer at a location halfway between the two support structures, wherein the fracture strength corresponds to the greatest force provided to the semiconductor wafer without breaking.

In some implementations of the example method, the treatment process increases a fracture strength of the semiconductor wafer in a range of about 65% to about 430%.

In some implementations of the example method, the treatment process increases a fracture strength of the semiconductor wafer in a range of about 120% to about 430%.

In some implementations of the example method, the treatment process increases a fracture strength of the semiconductor wafer in a range of about 230% to about 430%.

In some implementations of the example method, the treatment process is a non-mechanical treatment process.

In some implementations of the example method, the method includes performing a surface processing operation on the semiconductor wafer, wherein implementing the treatment process is performed prior to performing the surface processing operation.

In some implementations of the example method, the surface processing operation includes one or more of a grinding operation, lapping operation, polishing operation, chemical mechanical polishing operation, or electrochemical mechanical polishing operation.

In some implementations of the example method, the treatment processing includes a thermal anneal process, wherein the thermal anneal process includes heating the semiconductor wafer.

In some implementations of the example method, heating the semiconductor wafer includes heating the semiconductor wafer at a temperature in a range of about 1000° C. to about 2000° C.

In some implementations of the example method, heating the semiconductor wafer includes heating the semiconductor wafer at a temperature in a range of about 1300° C. to about 1700° C.

In some implementations of the example method, heating the semiconductor wafer includes heating the semiconductor wafer in an ambient gas.

In some implementations of the example method, the ambient gas is an inert gas.

In some implementations of the example method, the inert gas comprises argon.

In some implementations of the example method, the ambient gas comprises an etchant.

In some implementations of the example method, the etchant includes hydrogen.

In some implementations of the example method, the etchant includes silicon.

In some implementations of the example method, the ambient gas includes a forming gas, the forming gas having a concentration of hydrogen by weight of about 7% or less.

In some implementations of the example method, heating the semiconductor wafer includes heating the semiconductor wafer for a process period in a range of about 5 minutes to about 25 minutes.

In some implementations of the example method, heating the semiconductor wafer includes heating the semiconductor wafer for a process period in a range of about 10 minutes to about 20 minutes.

In some implementations of the example method, the treatment process includes a wet etch process, the wet etch process comprising exposing the semiconductor wafer to a wet chemical etchant.

In some implementations of the example method, exposing the semiconductor wafer to a wet chemical etchant includes exposing the semiconductor wafer to a wet chemical etchant at a temperature in a range of about 15° C. to about 100° C.

In some implementations of the example method, the wet chemical etchant includes gallium phosphide.

In some implementations of the example method, the wet chemical etchant includes an inorganic acid.

In some implementations of the example method, the inorganic acid includes one or more of nitric acid or hydrochloric acid.

In some implementations of the example method, the wet chemical etchant includes an hydroxide.

In some implementations of the example method, the hydroxide includes potassium hydroxide.

In some implementations of the example method, the treatment process includes a dry etch process, the dry etch process comprising exposing the semiconductor wafer to one or more species generated in a plasma.

In some implementations of the example method, the treatment process reduces a height of one or more peak topographical areas on a surface of the semiconductor wafer.

In some implementations of the example method, the treatment process reduces a surface roughness Sz of the semiconductor wafer.

In some implementations of the example method, removing a semiconductor wafer from a boule includes implementing a saw-based removal process, a laser-based removal process, or an implanted species-based removal process.

In some implementations of the example method, the semiconductor wafer includes silicon carbide.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A method of processing a semiconductor workpiece to increase a fracture strength of the semiconductor workpiece, comprising:
removing a semiconductor wafer from a boule; and
implementing a treatment process on the semiconductor wafer removed from the boule, the treatment process comprising a thermal treatment process that includes heating the semiconductor wafer in an ambient gas comprising an etchant or forming gas;
wherein heating the semiconductor wafer in the ambient gas comprises heating the semiconductor wafer at a temperature of about 1500° C. to about 2000° C. and increases the fracture strength of the semiconductor wafer to a range of about 17.5 Newtons or greater.

2. The method of claim 1, wherein the fracture strength is determined by placing the semiconductor wafer on two support structures and providing a force on the semiconductor wafer at a location halfway between the two support structures, wherein the fracture strength corresponds to a greatest force provided to the semiconductor wafer without breaking.

3. The method of claim 1, wherein the treatment process provides a fracture strength in a range of about 25 Newtons to about 75 Newtons.

4. The method of claim 1, further comprising performing a surface processing operation on the semiconductor wafer, wherein implementing the treatment process is performed prior to performing the surface processing operation.

5-9. (canceled)

10. The method of claim 1, wherein the etchant comprises hydrogen or silicon.

11. The method of claim 1, wherein the ambient gas comprises a forming gas, the forming gas having a concentration of hydrogen by weight of about 7% or less.

12-16. (canceled)

17. The method of claim 1, wherein the treatment process reduces a surface roughness Sz of the semiconductor wafer.

18. The method of claim 1, wherein the semiconductor wafer comprises silicon carbide.

19. (canceled)

20. A method of processing a silicon carbide semiconductor workpiece to increase a fracture strength of the silicon carbide semiconductor workpiece, comprising:
removing a silicon carbide semiconductor wafer from a boule; and
implementing a treatment process on the silicon carbide semiconductor wafer removed from the boule, the treatment process comprising a thermal treatment process comprising heating the silicon carbide semiconductor wafer to a temperature of about 1500° C. to about 2000° C.;
wherein the treatment process increases a fracture strength of the silicon carbide semiconductor wafer by about 15% or greater.

21. The method of claim 1, wherein removing the semiconductor wafer from the boule comprises implementing a saw-based removal process, a laser-based removal process, or an implanted species-based removal process.

22. (canceled)

23. A method of processing a semiconductor workpiece, comprising:
removing a semiconductor wafer from a boule;
implementing a treatment process on the semiconductor wafer removed from the boule, the treatment process comprising a thermal treatment process that includes heating the semiconductor wafer; and
performing a surface processing operation on the semiconductor wafer after implementing the treatment process;
wherein heating the semiconductor wafer in the ambient gas comprises heating the semiconductor wafer at a temperature of about 1300° C. to about 2000° C.
